(19) United States
(12) Patent Application Publication
(10) Pub. No.: US 2023/0282607 A1
(43) Pub. Date: Sep. 7, 2023

(54) METHODS AND APPARATUS FOR STACKED DIE WARPAGE CONTROL DURING MASS REFLOW

(71) Applicant: Micron Technology, Inc., Boise, ID (US)

(72) Inventors: Ting Yi Lin, Taichung (TW); Brandon P. Wirz, Boise, ID (US)

(21) Appl. No.: 18/111,525

(22) Filed: Feb. 17, 2023

Related U.S. Application Data
(60) Provisional application No. 63/316,253, filed on Mar. 3, 2022.

(51) Int. Cl. H01L 23/00; H01L 25/065

(52) U.S. Cl. CPC H01L 24/33; H01L 25/0657; H01L 24/05; H01L 24/06; H01L 24/16; H01L 24/14; H01L 24/29; H01L 24/32; H01L 24/73; H01L 24/81; H01L 24/83; H01L 24/92; H01L 24/30; H01L 2224/73204; H01L 2224/73253; H01L 2224/16145; H01L 2224/14132; H01L 2224/14181; H01L 2224/14517; H01L 2224/0557; H01L 2224/06181; H01L 2224/06517; H01L 2224/2919; H01L 2924/0665; H01L 2224/30134; H01L 2224/29034; H01L 2224/32145; H01L 2224/33181; H01L 2224/3303; H01L 2224/81024; H01L 2224/81815; H01L 2224/8113; H01L 2224/81065; H01L 2224/81203; H01L 2224/8313; H01L 2224/83862; H01L 2924/3511; H01L 2224/83951; H01L 2224/92125; H01L 2224/92225

(57) ABSTRACT

A semiconductor device assembly includes a die stack, a plurality of thermoset regions, and underfill material. The die stack includes at least first and second dies that each have a plurality of conductive interconnect elements on upper surfaces. A portion of the interconnect elements are connected to through-silicon vias that extend between the upper surfaces and lower surfaces of the associated dies. The plurality of thermoset regions each comprise a thin layer of thermoset material extending from the lower surface of the second die to the upper surface of the first die, and are laterally-spaced and discrete from each other. Each of the thermoset regions extends to fill an area between a plurality of adjacent interconnect elements of the first die. The underfill material fills remaining open areas between the interconnect elements of the first die.

### CROSS-REFERENCE TO RELATED APPLICATION(S)

The present application claims priority to U.S. Provisional Patent Application No. 63/316,253, filed Mar. 3, 2022, the disclosure of which is incorporated herein by reference in its entirety.

### TECHNICAL FIELD

The present technology is directed to semiconductor device packaging. More particularly, some embodiments of the present technology relate to techniques for controlling and/or reducing die warpage of thin dies in a die stack during the mass reflow process.

### BACKGROUND

Semiconductor dies of a die stack, particularly thin dies, can warp during the mass reflow process, which may result in failure of the device. Different areas of the wafer from which the dies are selected, such as inner, middle, and outer locations with reference to the center of the wafer, can warp different amounts when exposed to heat. Therefore, a stack of individual dies that come from different locations with respect to the center of the wafer can warp in different ways with respect to each other.

The warpage can lead to cold solder joints due to solder pulling up when the die stack is exposed to increasing and decreasing temperatures during the reflow process. In some cases, one or more dies in a die stack can warp such that the die(s) rotate and/or are disconnected. Therefore, an improved apparatus and/or process is desired to hold the die stack together to prevent separation and/or misalignment during the reflow process.

### BRIEF DESCRIPTION OF THE DRAWINGS

Many aspects of the present technology can be better understood with reference to the following drawings. The components in the drawings are not necessarily to scale. Instead, emphasis is placed on illustrating the principles of the present technology.

FIG. 1 is a side cross-sectional view of a semiconductor device assembly formed in accordance with the present technology.

FIG. 2 is a plan view of an upper surface of a singulated die that has small discrete thermoset regions applied in accordance with the present technology.

FIG. 3 is a flow chart of a method for assembling a die stack including both the thermoset region(s) and flux in accordance with the present technology.

FIG. 4 is a side cross-sectional view of the die stack that includes three dies, the thermoset regions, and flux in accordance with the present technology.

FIG. 5 is a generic illustration of the die cleaning process used in the method of FIG. 3 in accordance with the present technology.

FIG. 6 is a flow chart of a method for assembling a die stack including discrete thermoset region(s) and a thermal compression bonding (TCB) process in accordance with the present technology.

FIG. 7 shows a side cross-sectional view of the die stack that has been joined using the TCB process and method of FIG. 6 in accordance with the present technology.

FIG. 8 is a schematic view showing a system that includes a semiconductor device assembly configured in accordance with an embodiment of the present technology.

### DETAILED DESCRIPTION

In general, dies that are located in different locations on a wafer can experience different warpage behavior when subjected to temperature changes. In some cases, the warpage behavior can be associated with a variation in thickness across the wafer. Therefore, as a stack of singulated dies goes through the temperature changes associated with the reflow process, the warpage of one die can be different from that of another die in the stack. For example, as the temperature increases from a lower starting temperature, such as approximately 30 degrees Celsius, to a reflow temperature, such as approximately 260 degrees Celsius, one or more of the dies can experience a positive warpage that is not exactly the same as other dies in the stack. Then, as the temperature decreases back to a lower temperature, one or more of the dies can experience a negative warpage that is not exactly the same as other dies in the stack. As the temperature decreases, the solder interconnecting the stack of dies re-solidifies and “locks” the warp shape. In some embodiments, the solder re-solidifies around approximately 220 degrees Celsius. In some cases, dies may experience a negative warpage as temperature increases and a positive warpage as temperature decreases, and that the temperatures associated with the maximum reflow temperature and solder re-solidification may vary depending upon different material properties.

An expected advantage of some embodiments is that adjacent dies in a die stack will be held flat through the entire process of increasing and decreasing the temperature during the mass reflow process. Previously, a tacky flux was applied to the entire or substantial portions of a surface of the die (e.g., dipped, spreading non-conductive paste, etc.) to hold the interconnected adjacent dies flat. In some cases, dependent in part upon the thinness of the dies, the tacky flux is not strong enough to hold the dies flat throughout the temperature changes.

In embodiments of the current technology, at least one discrete region or area of a non-conductive material (e.g., thermoset region) is deposited or applied on an upper surface of a die, such as over or around a plurality of pillars or pads of the die. As discussed herein, the non-conductive material is referred to as a thermoset material as the material solidifies at a predetermined temperature during the mass reflow process. When two dies are aligned and stacked together, the thermoset material adheres to both dies, holding them together to maintain contact and rotational alignment throughout the reflow process. In some cases, multiple discrete regions of the thermoset material can be deposited proximate corners and/or edges to hold the dies securely, while in other cases, one or more discrete regions of the thermoset material can be deposited within a central region of the die.

Another expected advantage of some embodiments is that the use of one or more small regions of thermoset material may eliminate the need for a lengthy thermal compression bonding-type process that is needed when the entire bond line between adjacent dies is covered with a non-conductive film. Replacing the film that covers the surface entire area of the die with smaller areas that cover much less of the surface area of the die is more time efficient, allowing the dies to be tacked into place quickly prior to being sent to a mass reflow type oven, resulting in a reduced cycle time. An additional advantage is that the bond line is thin and thus non-wets and void formation is avoided. Further, as less surface area of the die is covered by adhesive material, less force is required to compress the layered dies together to ensure solder connection between adjacent dies.

In some embodiments, tacky flux or low residue non-cleaning flux can be used in addition to the at least one thermoset region. As the flux will mostly evaporate during reflow, either a typical type reflow oven or a formic acid type reflow oven can be used. In other embodiments, flux-less thermal compression bonding can be used with the at least one thermoset region of thermoset material, which may be accomplished, for example, by using a reduction environment type reflow oven (e.g., formic acid oven) to remove oxides.

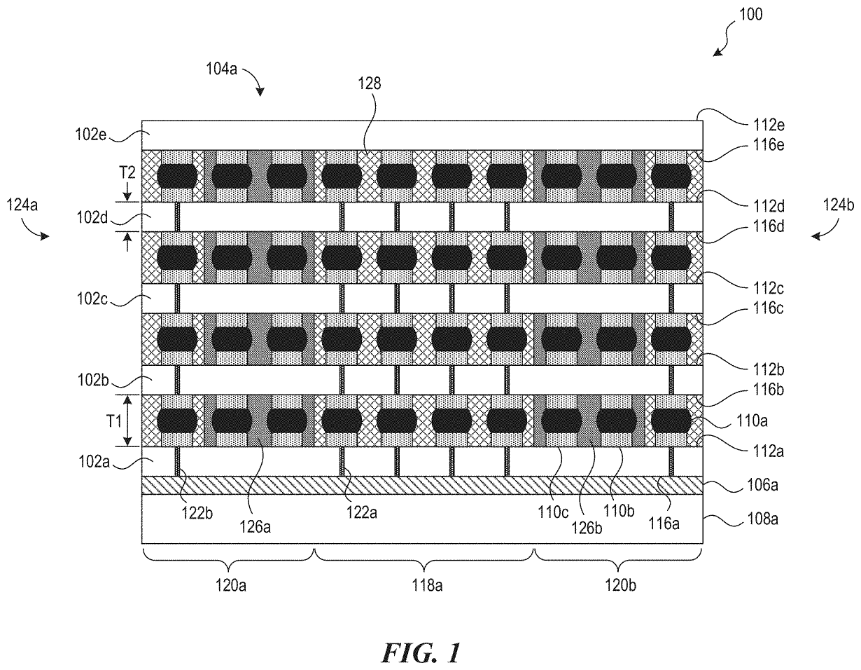

Numerous specific details are disclosed herein to provide a thorough and enabling description of embodiments of the present technology. A person skilled in the art, however, will understand that the technology may have additional embodiments and that the technology may be practiced without several of the details of the embodiments described below with reference to FIGS. 1-8. For example, some details of semiconductor devices and/or packages well known in the art have been omitted so as not to obscure the present technology. In general, it should be understood that various other devices and systems in addition to those specific embodiments disclosed herein may be within the scope of the present technology.

As used herein, the terms “vertical,” lateral,” “upper,” “lower,” “above,” “below,” “top,” and “bottom” can refer to relative directions or positions of features in the semiconductor devices in view of the orientation shown in the Figures. For example, “upper,” “uppermost,” or “top” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation. Also, as used herein, features that are, can, or may be substantially equal are within 10% of each other, or within 5% of each other, or within 2% of each other, or within 1% of each other, or within 0.5% of each other, or within 0.1% of each other, according to various embodiments of the disclosure.

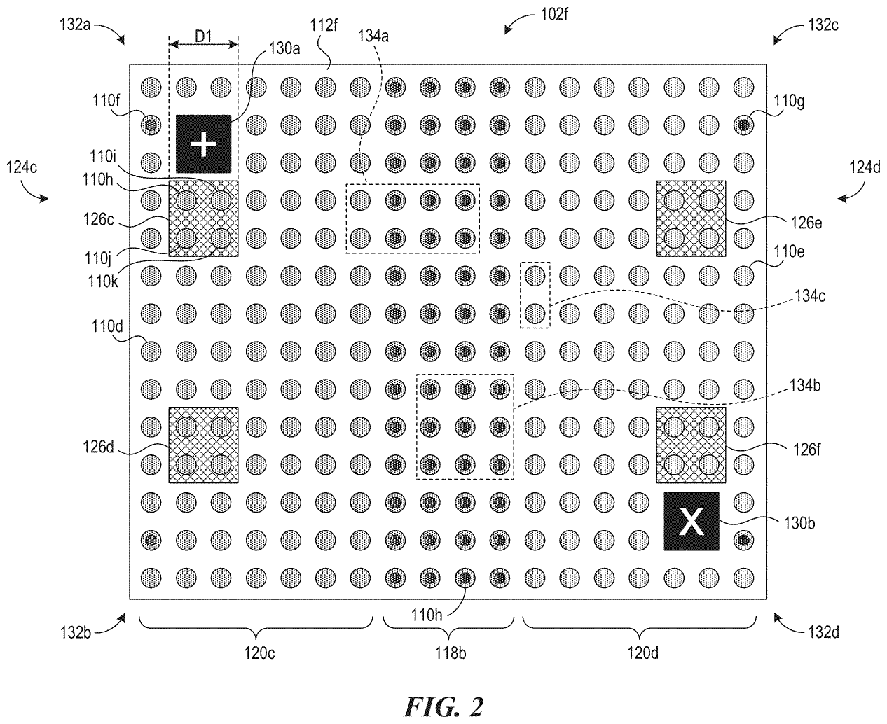

FIG. 1 illustrates an overview of the present technology, while FIGS. 2-8 illustrate further details of the present technology. Like reference numbers relate to similar components and features in FIGS. 1, 2, 4, 5, and 7. The present technology addresses the technical problem of die warpage control, which can cause cold solder joints, partial or total loss of adhesion, and/or misalignment between adjacent dies during the mass reflow process, and/or failure of the die stack. One or more small areas of non-conductive adhesive between at least some of the adjacent dies in the die stack can prevent the dies from warpage during the mass reflow process.

FIG. 1 is a side cross-sectional view of a semiconductor device assembly 100 in accordance with the present technology. The assembly 100 includes a plurality (N) of thin dies 102a, 102b, 102c, 102d, 102e stacked in a die stack 104a and attached to each other, wherein the die 102a is adjacent to the die 102b, the die 102b is adjacent to the die 102c, and so on. Each of the dies 102 can have a thickness T2, and adjacent dies are separated by a inter-die distance known as a bond line thickness T1. A bottom surface 116a of the bottom die 102a (e.g., an interface die) is adhered with an adhesive 106a to a removable carrier wafer 108a. The dies 102b-102e can be referred to as core dies. Although the die stack 104a is shown with five dies 102, the dies stack 104 can include more or less dies 102 (e.g., two, three, four, six, seven, eight, more than eight dies 102, etc.) Each of the dies 102 can be thin, such as 100 microns or less, 50 microns or less, 30 microns or less, etc. FIG. 1 shows a singulated die stack 104a; however, it should be understood that the assembly 100 can be formed either as a single die stack 104a, or formed at the wafer level and then singulated.

Each of the dies 102 can have a plurality of interconnect elements 110 (e.g., pads, pillars, under-bump metallization (UBM), etc.) on their upper surfaces 112a, 112b, 112c, 112d, 112e that can be arranged in a grid as shown further below in FIG. 2 (not all of the interconnect elements 110 are indicated separately). In some embodiments, an upper-most die (e.g., the die 102e in the die stack 104a) may omit interconnect elements on its upper surface 112e and any TSVs therein. It should be understood that the number of interconnect elements 110 shown is a representation only, and that each die 102 and/or chip would include many more interconnect elements 110. Each of the interconnect elements 110 can be connected to corresponding electrical connectors (e.g., such as pillars, pads or under-bump metallization (UBM), etc.) on the bottom surface 116b, 116c, 116d, 116e of the adjacent die 102 via solder. In some embodiments, a central region 118a of the die 102 can have live interconnect elements 110, or interconnect elements 110 that carry an electrical signal, and thus connect to through-silicon vias (TSVs) 122a (not all are indicated separately) that extend through the associated die 102. First and second peripheral regions 120a, 120b that are proximate opposite sides 124a, 124b, respectively, of the die 102 can include dummy interconnect elements 110b, 110c (not all are indicated separately) for thermal conduction and can also include one or more live interconnect elements 110a (not all are indicated separately) that can be used for test purposes or other signal conduction.

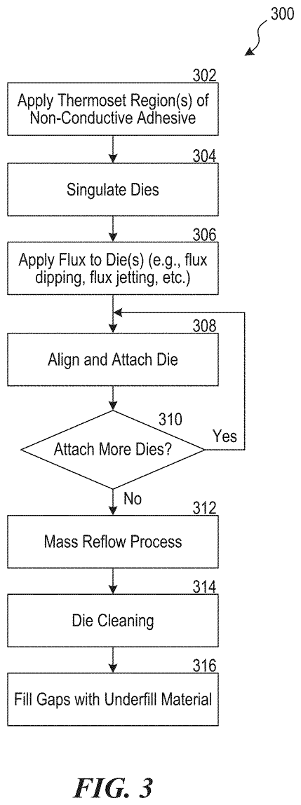

One or more small thermoset regions 126 of a non-conductive thermoset material can be deposited on or applied to the upper surface 112 of the die 102 (e.g., over or around one or more adjacent interconnect elements 110) or the bottom surface 116 of the die (e.g., over or around one or more adjacent electrical connectors) . As shown in the cross-sectional view of FIG. 1, each of the dies 102a-102d has two thermoset regions 126, although in some embodiments one or more die(s) 102 can have more than two thermoset regions 126, while other die(s) 102 can have less than two or zero thermoset regions 126. The non-conductive thermoset material (e.g., non-conductive film (NCF), thermosetting polymer, thermosetting epoxy, thin film, non-conductive adhesive material, etc.) can be applied, such as by using an inkjet printer or other deposition method, as discussed further below in FIG. 3.

As indicated in FIG. 1, the thermoset regions 126a, 126b are deposited on adjacent interconnect elements 110 in the first and second peripheral regions 120a, 120b to adhere the adjacent dies 102a, 102b together before and during mass reflow. The thermoset regions 126 can maintain bond line thickness T1 between the adjacent dies 102a, 102b and control and/or prevent die warpage. The thermoset regions 126 thus provide an adhesive force that holds adjacent dies 102 in contact with each other prior to being soldered together (e.g., during the solder reflow operation(s), compression bonding, thermal compression bonding, etc.), and also prevents lift and/or rotation of one or more die 102(s) that can result in cold solder joints, delamination, failure of the die stack 104a, etc. It should be understood that the bond line thickness T1 and the die thickness T2 are shown for clarity only, and that in some embodiments T2 can be thicker than T1 and/or T1 and T2 can be substantially the same thickness.

In some embodiments, the dies 102 can be assembled and/or formed into the die stack 104a on the carrier wafer 108a. After mass reflow processing of the die stack 104a is complete, unwanted materials such as flux residue, can be removed, if needed. The open areas between the interconnect elements 110 that are not filled with the thermoset material (e.g., the thermoset regions 126) can be filled with an underfill material 128, such as molded underfill (MUF) or capillary underfill (CUF), such as an epoxy. The materials for the thermoset material and the underfill material 128 are selected in part to ensure adhesion and compatibility between the materials.

FIG. 2 shows a plan view of the upper surface 112f of a singulated die (e.g., the die 1020 with small discrete thermoset regions 126c, 126d, 126e, 126f applied in accordance with the present technology. A plurality of the dummy or thermal interconnect elements 110d, 110e (not all of the dummy interconnect elements 110 are separately indicated) are located in the peripheral regions 120c, 120d along with several live interconnect elements 110f, 110g (not all of the live interconnect elements 110 are indicated) that may be used for testing purposes. Fiducial marks 130a, 130b are shown proximate two different corners 132a, 132d to aid in aligning the dies 102 during die stacking. A plurality of the live interconnect elements 110h (not all of the live interconnect elements 110 are indicated) can be located in the central region 118b. Other configurations of live interconnect elements 110, dummy interconnect elements 110, and fiducial marks 130 are contemplated, and thus these components are not limited to the placement as illustrated but can be anywhere within the area of the die 102.

The discrete thermoset regions 126c, 126d, 126e, 126f each substantially interfaces with four adjacent interconnect elements 110 (not all are marked individually). For example, the thermoset region 126c interfaces with the interconnect elements 110h, 110i, 110j, 110k, which are all dummy interconnect elements 110, but the embodiment is not so limited. In some embodiments, the thermoset material extends to fill areas between the associated adjacent interconnect elements 110 and may in some embodiments extend around an outer perimeter of the interconnect elements. Each of the thermoset regions 126 are positioned on the upper surface 112f of the die 102f and cover less than an entirety of a surface area of the upper surface 112f. The thermoset regions 126 are discrete or separate and not in contact with each other. For example, the thermoset regions 126c, 126d can be located proximate the side 124c of the die 102f and the thermoset regions 126e, 126f can be located proximate the opposite side 124d in the first and second peripheral regions 120c, 120d, respectively. Also as shown, the thermoset regions 126c, 126d, 126e, 126f can be located proximate different corners 132a, 132b, 132c, 132d, respectively, of the die 102f. In some embodiments, additional thermoset regions 126 can be located closer to or within the central region 118b of the die 102f, as indicated with boxes 134a, 134b, 134c that include different numbers of dummy and active interconnect elements 110.

In other embodiments, other numbers of thermoset regions 126 can be used, such as one, two, three, five, six, more than six, etc. Also, the thermoset regions 126 are not limited to interfacing with interconnect elements 110 that form a square (e.g., two-by-two square); instead, the thermoset regions 126 could be generally rectangular, generally circular, generally oval, or other regular or irregular shape. In further embodiments, the number of interconnect elements 110 connected by a single discrete thermoset region 126 can be less than four or greater than four.

The thermoset regions 126 can be located over areas of non-active interconnect elements 110 (e.g., thermally conductive interconnect elements 110 such as interconnect elements 110h-k) or active interconnect elements 110. The thermoset material of the thermoset region 126 does not impede or negatively impact the electrical connection between the interconnect elements 110 of the die 102 with the electrical connections on the bottom surface 116 (see FIG. 1) of the adjacent die 102.

In some embodiments, a lateral extent D1 of the thermoset regions 126 can be at least 30 microns, at least 50 microns, at least 100 microns, or greater than 100 microns. In other embodiments, the lateral extent D1 of the thermoset regions 126 can be determined at least in part on the capabilities and/or limitations of the dispensing apparatus and/or dispensing method being used to apply the thermoset material.

The number and size of the discrete thermoset regions 126 can be determined by the warpage of the dies 102, and in some cases, the die thickness T2 (see FIG. 1). In general, at least a portion of the thermoset region(s) 126 can be located in areas that experience greater warpage to provide a force to counteract the warpage experienced during the temperature changes of the reflow process. In some embodiments, a thinner die 102 may require less adhesive force, and thus fewer thermoset regions and/or smaller thermoset regions may be needed compared to a thicker, more rigid die 102. An advantage of embodiments of the present technology is that the adhesive force provided by the thermoset regions 126 is great enough to hold adjacent dies 102 together and overcome the warp that occurs when the die stack 104a is subjected to temperature changes during the mass reflow process.

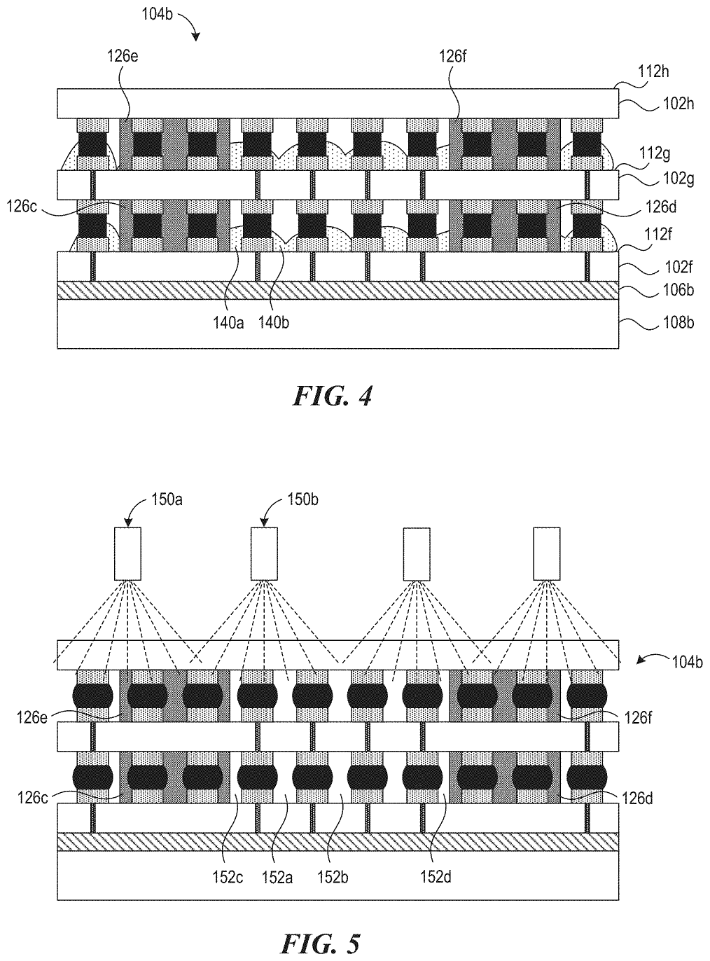

FIG. 3 is a flow chart of a method 300 for assembling a die stack 104 including both thermoset region(s) 126 and flux in accordance with the present technology. FIG. 4 is a side cross-sectional view of die stack 104b that includes three dies 102, a plurality of the thermoset regions 126, and flux 140. Turning to FIG. 5, the die cleaning process of the die stack 104b of FIG. 4 is generically illustrated. FIGS. 3-5 will be discussed together.

Referring to FIGS. 3 and 4, before the dies 102f, 102g, 102h are stacked to form the die stack 104b, one or more thermoset regions 126c, 126d of non-conductive adhesive (e.g., thermoset material) are applied to the upper surface 112f of the die 102f (block 302). Similarly, the thermoset regions 126e, 126f are applied to the upper surface 112g of the die 102g. This process is accomplished for each die 102 that is included in the die stack 104, except for the upper-most die 102h. In some embodiments the upper surface 112 can include interconnect elements (not illustrated) or other electrical connectors such as conductive pads, micro-bumps, etc. A material dispensing apparatus such as an inkjet printer, high precision inkjet printer, 3D inkjet printer, piezoelectric nozzle, dispensing nozzle, and/or other dispenser/dispensing technique can be used to apply the thermoset regions 126, which are thin enough to prevent unnecessary bond line disruption. The amount of material to dispense and type of dispenser can be determined, at least in part, to minimize the bond line thickness T1 (shown in FIG. 1) and ensure solder connection between, for example, the interconnect elements 110 and electrical connectors of adjacent dies 102. The dispensing apparatus/method can also be selected based on a desired lateral extent D1 (shown in FIG. 2) of the thermoset regions 126. The thermoset regions 126 can be aligned between the dies 102 as shown, but are not so limited.

The dies can be singulated, if needed (block 304). For example, the thermoset regions 126 can be applied to the desired locations on a wafer prior to singulation, or the thermoset regions 126 can be applied to the desired locations on individual dies 102. The flux 140a, 140b (not all areas of flux 140 are indicated separately) can be applied to the first die 102f (block 306), such as by flux dipping, flux jetting, or other deposition method known by a person of ordinary skill in the art. The flux can be used to remove the oxidation (e.g., metal oxide) or other contamination/material that occurs during the reflow of the solder (discussed further below). In some embodiments, the thermoset regions 126 and the flux 140 are applied to each die 102 that will have an adjacent die 102 attached over its upper surface 112. In other embodiments the thermoset regions 126 and/or flux 140 can be applied as needed, and thus one or more of the dies 102 in the die stack 104 can have a different number of thermoset regions 126 or zero thermoset regions 126, and may or may not have flux 140 applied.

The die 102 can be aligned and attached (block 308). For example, referring to FIG. 4, if the die 102f is a first die 102, the die 102f can be aligned and attached to the carrier 108b, such as with the adhesive 106b, as discussed above in FIG. 1. In other embodiments, if the die 102f is the first die, it may have been bonded to the carrier prior to the front-side processing used to fabricate the electrical interconnect elements 110. Otherwise, the die 102, such as the die 102g, can be aligned with and attached to the previous die 102 (e.g., 102f) in the die stack 104b. In some embodiments, one or more of the fiducial marks 130 as shown in FIG. 2 can be used to assist with the die alignment process. If more dies 102 are to be attached (block 310), the method returns to align and attach the next die 102 (block 308).

After all the dies 102 have been attached to form the die stack 104b, and any other desired components and/or attachments have been made (not shown), mass reflow is accomplished for interconnection of the dies 102 (block 312), such as with a typical type reflow oven or a formic acid reflow oven. As discussed above, as the temperature increases and decreases, for example, through the range of approximately 30 degrees Celsius to 240 degrees Celsius and back, the thermoset regions 126 hold the dies 102 together and prevent the dies 102 from warping, rotation, and/or other misalignment and/or disconnection. Therefore, the advantage of maintaining the bond line thickness T1 between the dies 102 throughout the reflow and re-solidification of the solder is realized, eliminating the cold solder joints experienced without the use of the thermoset regions 126.

A die cleaning process can be accomplished, if needed, to remove any flux residue (block 314). Turning to FIG. 5, the die cleaning process of the die stack 104b of FIG. 4 is generically illustrated with a series of nozzles 150a, 150b (not all are individually indicated). The thermoset material of the thermoset regions 126c remains within the die stack 104b, while any flux and/or flux residue is removed to ensure solder quality. In some embodiments, a low residue non-cleaning flux can be used instead of a tacky flux. Therefore, the die cleaning process (at block 314) can be optional if the flux residue has baked out during the mass reflow process (at block 312).

Gaps 152a, 152b between the interconnect elements 110, and gaps 152c, 152d (not all gaps 152 are indicated separately) between the interconnect elements 110 and the thermoset regions 126, can be filled with the underfill material 128 (block 316) to protect the interconnect elements 110 and/or interconnections, as shown in FIG. 1. The underfill material 128 (e.g., CUF and/or MUF) are compatible with the material used for the thermoset regions 126 to ensure adhesion between the materials.

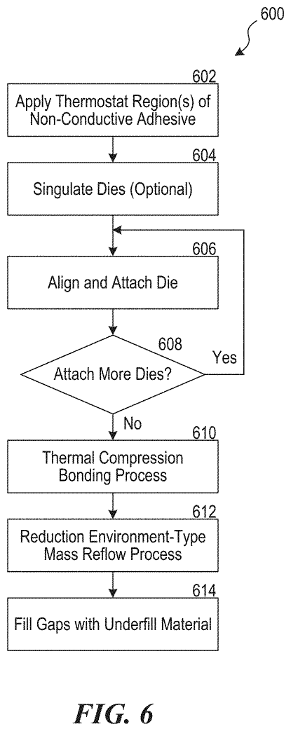

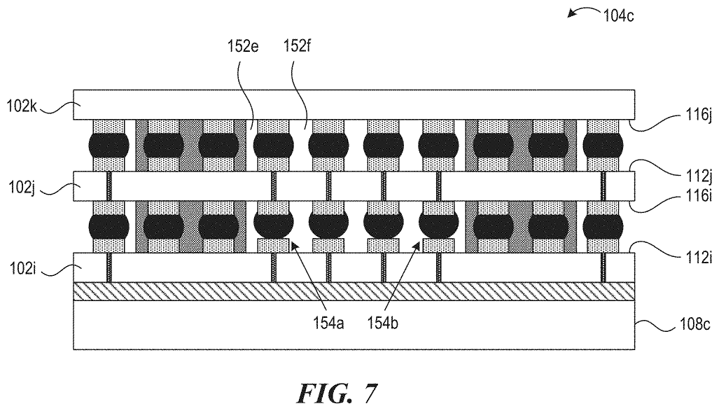

FIG. 6 is a flow chart of a method 600 for assembling the die stack 104 using discrete thermoset region(s) 126 and thermal compression bonding (TCB) in accordance with the present technology. FIG. 7 shows a side cross-sectional view of die stack 104c that has been joined using a TCB process, and will be discussed together with FIG. 6. Blocks in FIG. 6 that are substantially similar to blocks in the method of FIG. 3 will not be explained in detail in the discussion of FIG. 6.

Turning to FIG. 6, one or more discrete thermoset regions 126 of non-conductive adhesive are applied to the upper surface 112 or the bottom surface 116 of the die(s) (block 602) and the dies 102 can be singulated, if needed (block 604). The die 102 can be aligned and attached (block 606). If more dies 102 are to be attached (block 608), the method returns to block 606 to align and attach the next die 102.

After all of the dies 102 have been attached to form the die stack 104c, and any other desired components and/or attachments have been made (not shown), the TCB process is accomplished by applying force and heat simultaneously to bond the dies 102i, 102j, 102k and substrate 108c (block 610). In some embodiments, the TCB process partially solders the interconnects between the interconnect elements 110 on the upper surfaces 112i, 112j and the electrical connections on the bottom surfaces 116i, 116j. In some embodiments the die stack 104c may be subjected to heat without pressure, and thus a heating step to hold the dies 102i, 102j, 102k together can be accomplished instead of the TCB process at block 610.

A reduction environment type mass reflow is accomplished for interconnection of the dies 102 (block 612), such as with a formic acid reflow oven. In some embodiments, the use of TCB (at block 610) may result in partial solder wetting of some connections 154a, 154b due to oxide, and thus the additional step of mass reflow is desirable and/or necessary. In other embodiments, the TCB process may set/cure the thermoset regions 126 and result in solder interconnections that are acceptable and thus no mass reflow may be needed.

In some embodiments, die cleaning may be accomplished as discussed above (not shown in FIG. 6). The gaps 152e, 152f (not all of the gaps are indicated individually) between the interconnect elements 110 and between the interconnect elements 110 and the thermoset regions 126 can be filled with the underfill material 128 to protect the interconnections (block 614), as shown in FIG. 1.

In other embodiments, applying to both configurations that use flux 140 and configurations that do not use flux 140, different die cleaning processes can be used, e.g., plasma-type cleaning, oxygen, argon, and/or hydrogen cleaning processes. If an additional cleaning step is used, it may not be necessary to complete the mass reflow with a formic acid reflow oven.

Although in the foregoing example embodiments package assemblies have been described and illustrated as including laterally-spaced discrete thermoset regions between the adjacent semiconductor dies, in other embodiments of the present disclosure similar laterally-spaced discrete thermoset regions may be provided between a die and a substrate (e.g., in a single-device package flip-chip assembly or the like).

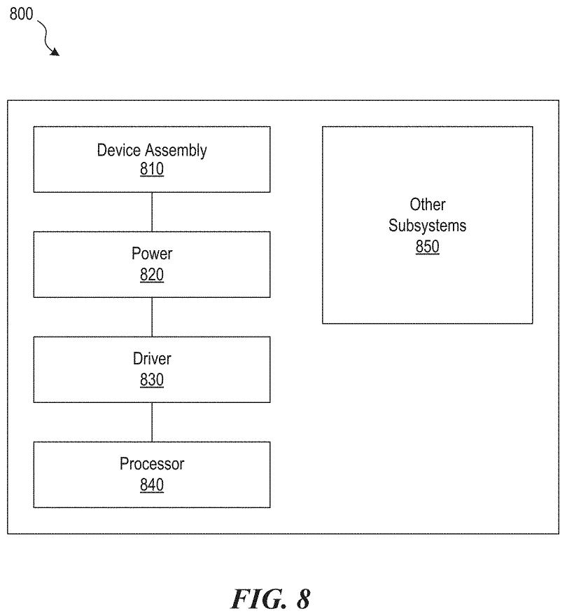

Any one of the semiconductor devices, assemblies, and/or packages described above with reference to FIGS. 1 through 7 can be incorporated into any of a myriad of larger and/or more complex systems, a representative example of which is system 800 shown schematically in FIG. 8. The system 800 can include a semiconductor device assembly 810, a power source 820, a driver 830, a processor 840, and/or other subsystems or components 850. The semiconductor device assembly 810 can include features generally similar to those of the semiconductor device assemblies described above. The resulting system 800 can perform any of a wide variety of functions such as memory storage, data processing, and/or other suitable functions. Accordingly, representative systems 800 can include, without limitation, hand-held devices (e.g., mobile phones, tablets, digital readers, and digital audio players), computers, vehicle and other machines and appliances. Components of the system 800 may be housed in a single unit or distributed over multiple, interconnected units (e.g., through a communications network). The components of the system 800 can also include remote devices and any of a wide variety of computer readable media.

This disclosure is not intended to be exhaustive or to limit the present technology to the precise forms disclosed herein. Although specific embodiments are disclosed herein for illustrative purposes, various equivalent modifications are possible without deviating from the present technology, as those of ordinary skill in the relevant art will recognize. In some cases, well-known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein.

Throughout this disclosure, the singular terms “a,” “an,” and “the” include plural referents unless the context clearly indicates otherwise. Similarly, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Additionally, the term “comprising” is used throughout to mean including at least the recited feature(s) such that any greater number of the same feature and/or additional types of other features are not precluded. Reference herein to “one embodiment,” “some embodiment,” or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

From the foregoing, it will be appreciated that specific embodiments of the present technology have been described herein for purposes of illustration, but that various modifications may be made without deviating from the scope of the invention. The present technology is not limited except as by the appended claims.

I/We claim:

1. A semiconductor device assembly, comprising:
a die stack comprising at least first and second dies, the first die having an upper surface on which are disposed a plurality of conductive interconnect elements extending to corresponding electrical connectors on a lower surface of the second die;
a plurality of laterally-spaced discrete thermoset regions between the first and second dies, each thermoset region comprising a layer of thermoset material extending from the lower surface of the second die to the upper surface of the first die, wherein each of the two thermoset regions extends to fill an area between a plurality of adjacent interconnect elements of the first die; and
an underfill material filling remaining open areas between the plurality of interconnect elements of the first die.

2. The semiconductor device assembly of claim 1, wherein the plurality of thermoset regions includes two thermoset regions located proximate opposite edges of the first die.

3. The semiconductor device assembly of claim 1, wherein the plurality of thermoset regions includes four thermoset regions located proximate four corresponding corners of the first die.

4. The semiconductor device assembly of claim 1, wherein the area between a plurality of adjacent interconnect elements of the first die is bounded by four interconnect elements arranged in a two-by-two square.

5. The semiconductor device assembly of claim 1, wherein the thermoset material comprises one of a non-conductive adhesive material, a non-conductive film (NCF), a thermosetting polymer, a thermosetting epoxy, or a thin film.

6. The semiconductor device assembly of claim 5, wherein the underfill material is compatible with the thermoset material.

7. The semiconductor device assembly of claim 1, wherein each of the thermoset regions are at least 30 microns in lateral extent.

8. The semiconductor device assembly of claim 1, wherein each of the thermoset regions are at least 100 microns in lateral extent.

9. The semiconductor device assembly of claim 1, wherein the plurality of thermoset regions includes a thermoset region located in a central region of the upper surface of the first die.

10. The semiconductor device assembly of claim 1, wherein the electrical connectors are interconnected by solder to the plurality of conductive interconnect elements on the upper surface of the first die.

11. A method for adhering adjacent dies together in a die stack to minimize die warpage, comprising:
applying a plurality of thermoset regions of non-conductive adhesive material to an upper surface of a first die with a material dispensing apparatus, wherein each thermoset region covers less than an entirety of a surface area of the upper surface of the first die and the two thermoset regions are laterally spaced and discrete from each other;
stacking a second die on the first die to form a die stack, wherein the two thermoset regions adhere to a bottom surface of the second die; and
thermally curing the non-conductive adhesive material in a mass reflow process of the die stack.

12. The method of claim 11, wherein the material dispensing apparatus is one of an inkjet printer, high precision inkjet printer, 3D inkjet printer, piezoelectric nozzle, or dispensing nozzle.

13. The method of claim 11, wherein the each of the plurality of thermoset regions is applied to or between a plurality of interconnect elements on the upper surface of the first die.

14. The method of claim 11, wherein the plurality of thermoset regions includes two thermoset regions located proximate opposite edges of the first die.

15. The method of claim 11, wherein the plurality of thermoset regions includes four thermoset regions located proximate four corresponding corners of the first die.

16. The method of claim 11, further comprising applying flux to at least a portion of the surface area of the upper surface of the first die before thermally curing the non-conductive adhesive material.

17. The method of claim 11, further comprising applying force and heat simultaneously to the die stack in a thermal compression bonding process in advance of the thermally curing the non-conductive adhesive material.

18. A semiconductor device assembly, comprising:
a die stack comprising N dies and an uppermost die, wherein N is an integer greater than or equal to three, each of the N dies including a plurality of conductive interconnect elements on upper surfaces, wherein a portion of the interconnect elements are connected to through-silicon vias (TSVs) that extend between the upper surfaces and lower surfaces of associated ones of the N dies;
a plurality of laterally-spaced discrete thermoset regions between the first and second dies, each thermoset region comprising a layer of thermoset material extending from the lower surface of the second die to the upper surface of the first die, wherein each of the two thermoset regions extends to fill an area between a plurality of adjacent interconnect elements of the first die; and
an underfill material filling remaining open areas between the interconnect elements of the N−1 dies.

19. The semiconductor device assembly of claim 18, wherein the thermoset material comprises one of a non-conductive adhesive material, a non-conductive film (NCF), a thermosetting polymer, a thermosetting epoxy, or a thin film.

20. The semiconductor device assembly of claim 18, wherein each thermoset region is at least 30 microns in lateral extent, at least 50 microns in lateral extent, or at least 100 microns in lateral extent.
